(19) United States
(12) Patent Application Publication
(10) Pub. No.: US 2011/0215397 A1
(43) Pub. Date: Sep. 8, 2011

(54) HIGH CELL DENSITY TRENCHED POWER SEMICONDUCTOR STRUCTURE AND FABRICATION METHOD THEREOF

(75) Inventor: HSIU WEN HSU, HSINCHU COUNTY (TW)

(73) Assignee: GREAT POWER SEMICONDUCTOR CORP., TAIPEI COUNTY (TW)

(21) Appl. No.: 12/859,491

(22) Filed: Aug. 19, 2010

(30) Foreign Application Priority Data
Mar. 5, 2010 (TW) 99106370

(51) Int. Cl. H01L 29/78; H01L 21/28

(52) U.S. Cl. 257/330; 438/589; 257/E21.158; 257/E29.255

(57) ABSTRACT

The fabrication method of a high cell density trenched power semiconductor structure is provided. The fabrication method comprises the steps of: a) forming at least a gate trench in a substrate with a silicon oxide patterned layer formed thereon, said silicon oxide patterned layer having at least an open aligned to the gate trench; b) forming a polysilicon gate in the gate trench; c) forming a dielectric structure in the open, the dielectric structure has a sidewall thereof being lined with an etching protection layer; d) removing the silicon oxide patterned layer by selective etching; and e) forming a spacer on a side surface of the dielectric structure to define at least a contact window.

### BACKGROUND OF THE INVENTION

(1) Field of the Invention

The present invention relates to a trenched power semiconductor structure and a fabrication method thereof, and more particularly relates to a high cell density trenched power semiconductor structure and a fabrication method thereof.

(2) Description of the Prior Art

FIGS. 1A to 1C are schematic cross-section views showing a fabrication method of the gate structure of a typical trenched power semiconductor structure. As shown in FIG. 1A, firstly, a gate trench 120 is formed in a silicon substrate 110. Then, a gate oxide layer 130 is formed on the inner surfaces of the gate trench 120. Afterward, a polysilicon film is deposited on the silicon substrate 110. The unwanted portion of the polysilicon film is then removed by using the method of etching back so as to form a polysilicon gate 140 in the gate trench 120.

Next, as shown in FIG. 1B, an ion implantation process is carried out to implant dopants into the silicon substrate 110 so as to form the body 150 surrounding the gate trench 120. Thereafter, another ion implantation process follows to implant dopants of different conductive type into the upper portion of the body 150 so as to form the source region 160. Next, as shown in FIG. 1C, a dielectric film 170 is deposited on the silicon substrate 110 and fills the gate trenches 120. Then, the source contact window 180 is formed in the dielectric film 170 and the body 150 for exposing the source region 160 by using lithographic and etching processes.

It is noted that the distance between the gate trench 120 and the contact window 180 would be restricted by critical dimensions of the trench 120 and the contract window 180 as well as alignment tolerance of lithographic steps. Variations of the distance between the gate trench 120 and the contact window 180 may result in the problems including leakage current, threshold voltage variation, or poor avalanche ruggedness.

Accordingly, it is a topic in the art to increase cell density of the trenched power semiconductor structure with the above mentioned problems being properly resolved.

### SUMMARY OF THE INVENTION

It is an object of the present invention to provide a high cell density trenched power semiconductor structure and a fabrication method thereof, which features self alignment fabrication steps to overcome the limitations of critical dimension and alignment tolerance.

To achieve the above mentioned object, a fabrication method of a high cell density trenched power semiconductor structure is provided. The fabrication method comprises the steps of: a) forming at least a gate trench in a substrate with a silicon oxide patterned layer formed thereon, said silicon oxide patterned layer having at least an open aligned to the gate trench; b) forming a polysilicon gate in the gate trench; c) forming a dielectric structure, which has a sidewall thereof being lined with an etching protection layer, in the open; d) removing the silicon oxide patterned layer by selective etching; and e) forming a spacer on a side surface of the dielectric structure to define at least a contact window.

According to the above mentioned fabrication method, a high cell density trenched power semiconductor structure is also provided in the present invention. The high cell density trenched power semiconductor structure has a silicon substrate, a gate trench, a polysilicon gate, a body, a source region, a dielectric structure, and a spacer. The gate trench is located in the silicon substrate. The polysilicon gate is located in the gate trench. The body is located in the silicon substrate and surrounds the gate trench. The source region is located in the body. The dielectric structure is located above the polysilicon gate and protruded from the gate trench. A maximum width of the dielectric structure is smaller than that of the gate trench. The spacer is located on a side surface of the dielectric structure for defining at least a contact window to expose the source region.

In contrast with the fabrication method of the traditional trenched power semiconductor structure, in which the distance between the gate trench and the contact window is restricted by the critical dimensions of the gate trench and the contact window as well as alignment tolerance, the trenched power semiconductor structure applies the self-alignment method in the steps of forming the dielectric structure above the polysilicon gate and of forming the spacer on the side surface of the dielectric structure. Thus, the limitations about critical dimension and alignment tolerance can be overcome and the object of increasing cell density can be achieved.

### BRIEF DESCRIPTION OF THE DRAWINGS

The present invention will now be specified with reference to its preferred embodiment illustrated in the drawings, in which:

FIGS. 1A to 1C are schematic cross-section views showing a fabrication method of a typical trenched power semiconductor structure.

FIGS. 2A to 2F are schematic cross-section views showing a fabrication method of a high cell density trenched power semiconductor structure in accordance with a first embodiment of the present invention.

FIGS. 3A to 3D are schematic cross-section views showing a fabrication method of a high cell density trenched power semiconductor structure in accordance with a second embodiment of the present invention.

FIGS. 4A to 4H are schematic cross-section views showing a fabrication method of a high cell density trenched power semiconductor structure in accordance with a third embodiment of the present invention.

FIGS. 5A to 5E are schematic cross-section views showing a fabrication method of a high cell density trenched power semiconductor structure in accordance with a fourth embodiment of the present invention.

FIGS. 6A to 6D are schematic cross-section views showing a fabrication method of a high cell density trenched power semiconductor structure in accordance with a fifth embodiment of the present invention.

FIGS. 7A to 7E are schematic cross-section views showing a fabrication method of a high cell density trenched power semiconductor structure in accordance with a sixth embodiment of the present invention.

FIGS. 8A to 8E are schematic cross-section views showing a fabrication method of a high cell density trenched power semiconductor structure in accordance with a seventh embodiment of the present invention.

FIGS. 9A to 9B are schematic cross-section views showing a fabrication method of a high cell density trenched power semiconductor structure in accordance with a eighth embodiment of the present invention.

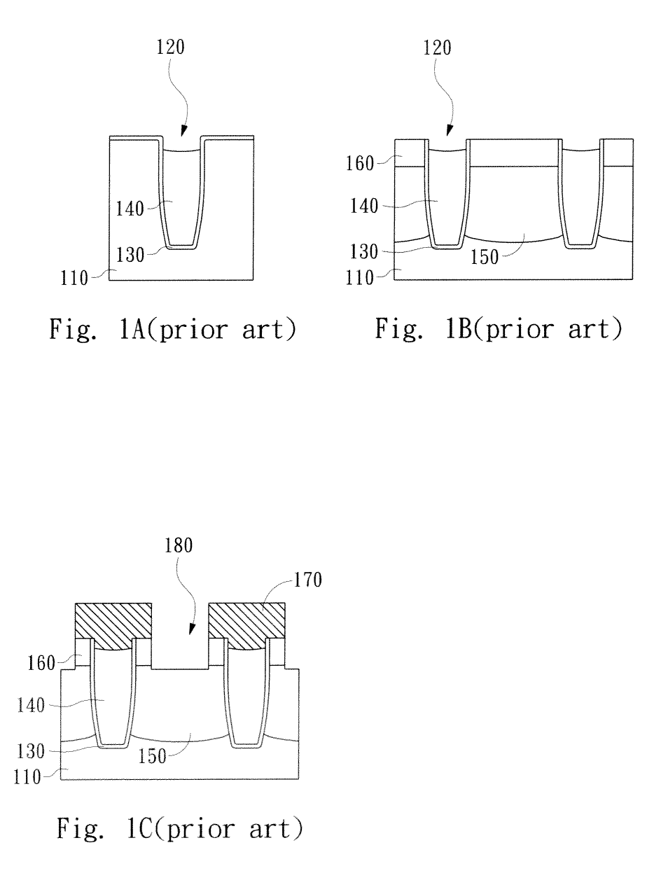

### DESCRIPTION OF THE PREFERRED EMBODIMENT

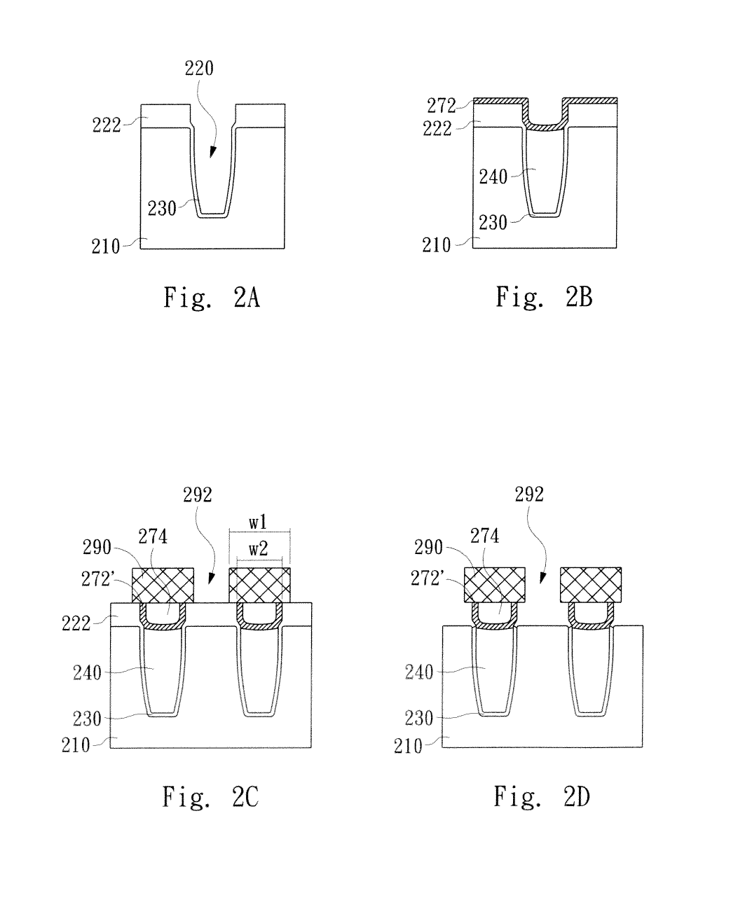

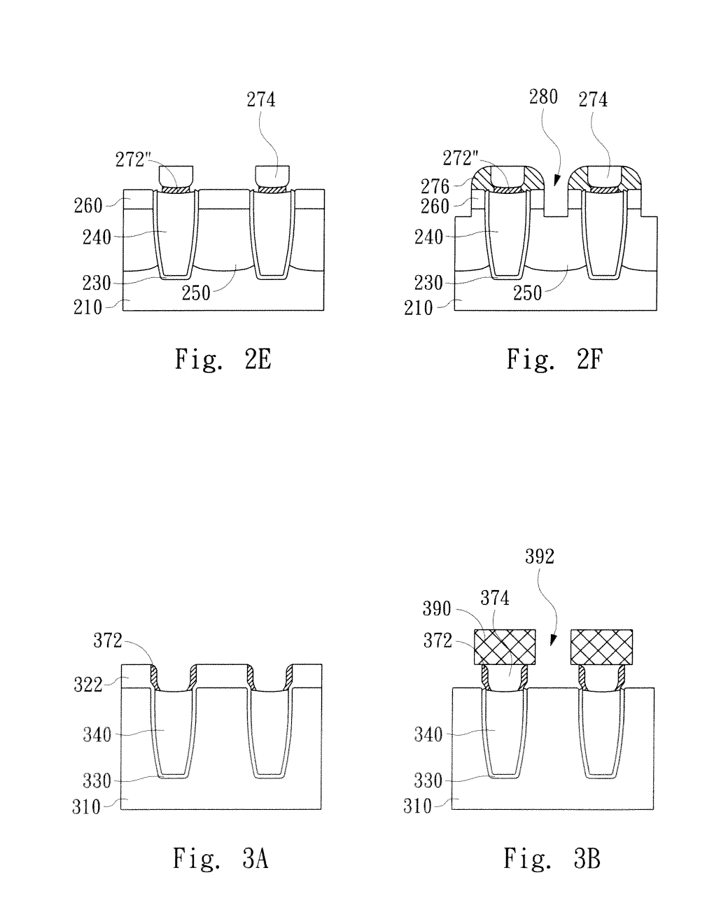

FIGS. 2A to 2F are schematic cross-section views showing a fabrication method of a high cell density trenched power semiconductor structure in accordance with a first embodiment of the present invention. As shown in FIG. 2A, firstly, a silicon oxide patterned layer 222, such as a hard mask, is formed on a silicon substrate 210 for defining at least a gate trench 220. Thereafter, the silicon substrate is etched through the silicon oxide patterned layer 222 to form the gate trench 220 therein. Afterward, a gate dielectric layer 230, such as a gate oxide layer, is formed on the inner surfaces of the gate trench 220.

Next, as shown in FIG. 2B, a polysilicon gate 240 is formed in the gate trench 220. The detail fabrication steps of the polysilicon gate 240 are described below for example. Firstly, a polysilicon layer is deposited on the silicon substrate 210 and the silicon oxide patterned layer 222 and fills the gate trenches 220. Then, the unwanted portion of the polysilicon layer is removed by etching back to leave the polysilicon gate 240 in the gate trench 220. It is noted that there should be enough space left in the gate trench 220 for the following steps. As a preferred embodiment, the upper surface of the polysilicon gate 240 is substantially aligned to the upper surface of the silicon substrate 110.

Next, an etching protection layer 272 is conformally formed on the silicon oxide patterned layer 222 and the polysilicon gate 240. The etching protection layer 272 may be composed of polysilicon or silicon nitride. In addition, there shows a concave on the etching protection layer 272 corresponding to the open of the silicon oxide patterned layer 222. Then, as shown in FIG. 2C, a dielectric structure 274, which may be composed of silicon oxide, is formed in the open of the silicon oxide patterned layer 222 and substantially fills the concave on the etching protection layer 272.

The dielectric structure 274 may be fabricated by using the following steps for example. Firstly, a dielectric layer is deposited on the etching protection layer 272 and fills the open of the silicon oxide patterned layer 222. Then, the unwanted portion of the dielectric layer is removed by etching back to leave the dielectric structure 274 on the polysilicon gate 240. The maximum width of the dielectric structure 274 is smaller than the width of the open of the gate trench 220.

Next, the portion of the etching protection layer 272 covering the upper surface of the silicon oxide patterned layer 222 is removed to leave the portion, which is labeled by 272′, covering the sidewalls of the open of the silicon oxide patterned layer 222. The chemical mechanical polishing (CMP) process or the selective etching process with the dielectric structure 274 as the etching mask may be used in the present step.

Next, a photo-resist layer 290 utilized for selectively removing the silicon oxide patterned layer 222 is formed to cover the dielectric structure 274. The only requirement for the photo-resist layer 290 is that the open 292 of the photo-resist layer 290 should be wide enough for removing the silicon oxide patterned layer 222 therebelow. The line width w1 of the photo-resist layer 290 does not have to be identical to the width of the dielectric structure 274, and the pattern of the photo-resist layer 290 does not have to align the dielectric structure 274. Thus, the line width w1 of the photo-resist layer 290 may be greater than the width w2 of the open of the gate trench 220 to meet the alignment errors.

Next, as shown in FIG. 2D, the silicon oxide patterned layer 222 is removed through the photo-resist layer 290 but the etching protection layer 272′ on the sidewalls of the dielectric structure 274 is remained. The typical selectively etching process can be applied in the present step. For example, as the etching protection layer 272′ is formed of polysilicon material, the etching technology featuring high etch selectivity of silicon oxide over polysilicon can be used. As the etching protection layer 272′ is formed of silicon nitride, the etching technology featuring high etch selectivity of silicon oxide over silicon nitride can be used. It should be noted that because the sidewall and the upper surface of the dielectric structure 274 are shielded by the etching protection layer 272′ and the photo-resist layer 290 respectively, the dielectric structure 274, which may be formed of silicon oxide, would not be etched in the present etching step.

Next, as shown in FIG. 2E, the photo-resist layer 290 is removed, and then the exposed portion of the etching protection layer 272′ is removed to leave the portion of the etching protection layer, which is labeled by 272″, at the bottom of the dielectric structure 274. The etching technology with high etch selectivity of etching protection layer 272′ over dielectric structure 274 can be applied in the present etching step.

In the present embodiment, the photo-resist layer 290 and the portion of the etching protection layer 272 on the sidewall of the dielectric structure 274 are removed by using two distinct etching steps. However, the present embodiment can be performed without the etching step solely for removing the etching protection layer 272′ on the sidewall of the dielectric structure 274 as the etching protection layer 272 is formed of silicon nitride.

Next, an ion implantation step for forming a body 250 surrounding the gate trench 220 is carried out by using the dielectric structure 274 as a mask. Then, another ion implantation step is performed to form source regions 260 with the conductive type opposite to that of the body 250 in the surface region of the silicon substrate 210.

Next, as shown in FIG. 2F, a spacer 276 is formed on the side surface of the dielectric structure 274 to define at least a contact window 280. Thereafter, an etching step is performed to form the contact window 280 in the silicon substrate 210 so as to expose the source region 260 in surface region of the silicon substrate 210.

As mentioned, in accordance with the present embodiment, the dielectric structure 274 is defined by using the open of the silicon oxide patterned layer 222 so as to have the dielectric structure 274 self-aligned to the gate trench 220. In addition, by using the spacer 276 on the side surface of the dielectric structure 274 to define the contact window 280, the source contact mask can be skipped. Accordingly, unwanted limitations of critical dimensions of the gate trench 220 and the contact window 280 as well as alignment error can be minimized, and the distance between the gate trench 220 and the contact window 280 can be further reduced to achieve the object of increasing cell density.

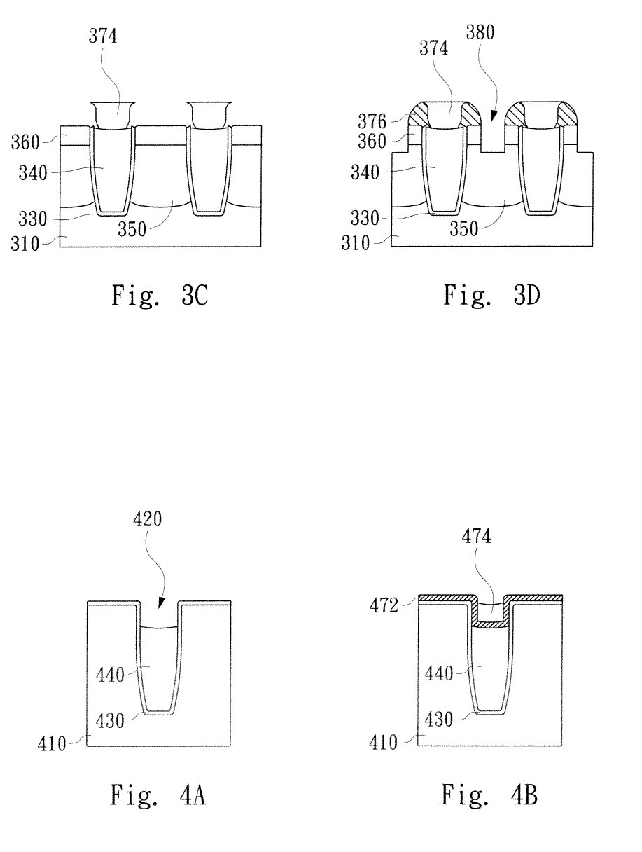

FIGS. 3A to 3D are schematic cross-section views showing a second embodiment of the fabrication method of the high cell density trenched power semiconductor structure in accordance with a second embodiment of the present invention, wherein the fabrication step of FIG. 3A is next to the fabrication step as shown in FIG. 2B. Different from the first embodiment, the present embodiment applies an anisotropic etching step right after the formation of the etching protection layer for removing the etching protection layer on the upper surfaces of the silicon oxide patterned layer 322 and the polysilicon gate 340. The portion of the etching protection layer on the sidewall of the open of the silicon oxide patterned layer 322, which is labeled by 372, is left.

Next, as shown in FIG. 3B, the dielectric structure 374 is filled into the open of the silicon oxide patterned layer 322. The dielectric structure 374 contacts the upper surface of the polysilicon gate 340. Thereafter, similar to the corresponded steps of the first embodiment, the photo-resist layer 390 is formed on the upper surface of the dielectric layer 374, and then the silicon oxide patterned layer 322 is removed through the photo-resist layer 390 but the etching protection layer 372 is remained. Afterward, as shown in FIG. 3C, the photo-resist layer 390 is removed, and then the exposed portion of the etching protection layer 372 is removed. Because the etching protection layer 372 merely covers the sidewall of the dielectric structure 374, the whole etching protection layer 372 would be removed in the present etching step.

Next, a body 350 and a source region 360 are formed in the silicon substrate 310 in a serial. Then, as shown in FIG. 3D, a spacer 376 is formed on the side surface of the dielectric structure 374 to define the location of the contact window 380. Thereafter, the silicon substrate 310 is etched through the spacer 376 to form the contact window 380 for exposing the source region 360.

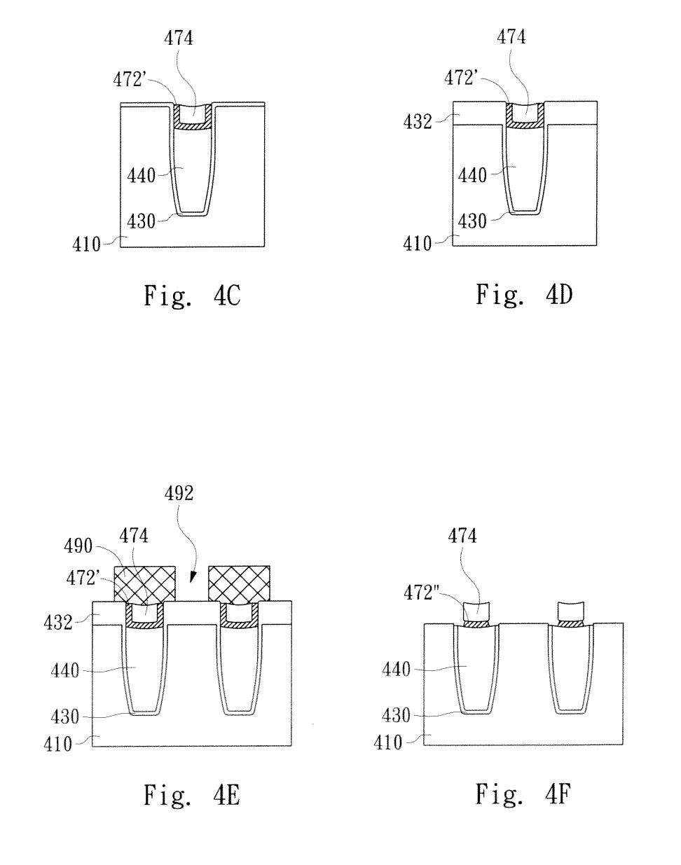

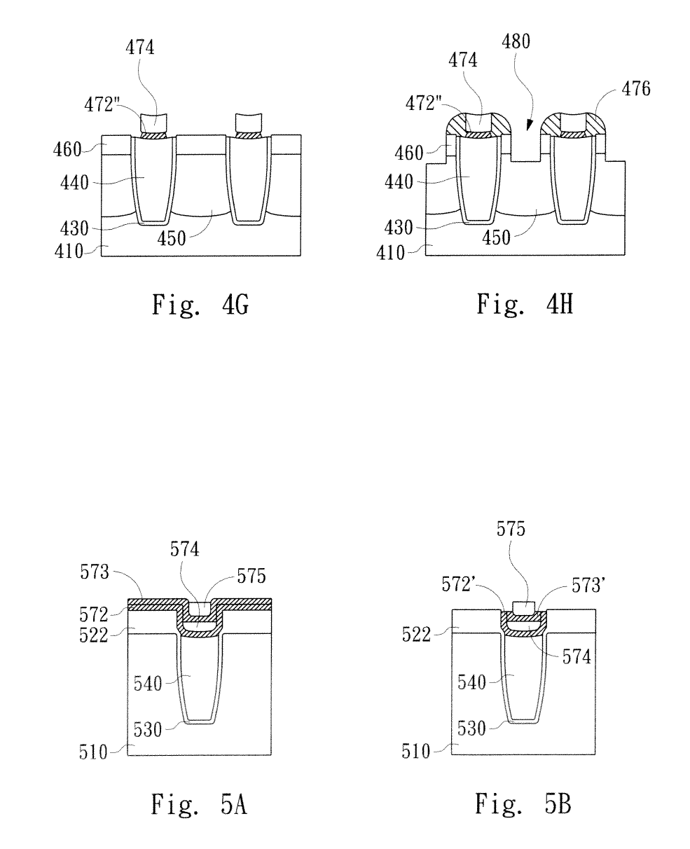

FIGS. 4A to 4H are schematic cross-section views showing a fabrication method of a high cell density trenched power semiconductor structure in accordance with a third embodiment of the present invention. As shown in FIG. 4A, at least a gate trench 420 is firstly formed in a silicon substrate 410. The gate trench 420 may be formed in the silicon substrate 410 by using a patterned layer (not shown) as an etching mask. After the formation of the gate trench 420, the patterned layer is removed to expose the upper surface of the silicon substrate 410.

Next, a gate dielectric layer 430 is formed to line the inner surfaces of the gate trench 420. Then, a polysilicon gate 440 is formed in the gate trench 420. It is noted that a predetermined distance is kept between the upper surface of the polysilicon gate 440 and the upper edge of the gate trench 420.

Thereafter, as shown in FIG. 4B, an etching protection layer 472 is conformally formed on the silicon substrate 410 and the polysilicon gate 440. The etching protection layer 472 may be formed of polysilicon or silicon nitride. In addition, there shows a concave on the etching protection layer 472 corresponding to the gate trench 420. Thereafter, a dielectric structure 474 is formed in the concave. The dielectric structure 474 is substantially aligned to the polysilicon gate 440, and a maximum width of the dielectric structure 474 is smaller than the width of the open of the gate trench 420. The dielectric structure 474 may be fabricated by using the method as depicted in the first embodiment for example.

Next, as shown in FIG. 4C, the portion of the etching protection layer 472 on the upper surface of the silicon substrate 410 is removed but the portion in the gate trench 420, which is labeled by 472′, is remained. The selective etching process may be adapted in the present etching step for removing the exposed portion of the etching protection layer 472 but keeping the dielectric structure 474 as well as the portion of the etching protection layer 472′ shielded by the dielectric structure 474.

Next, as shown in FIG. 4D, an oxidizing step is carried out to form a silicon oxide layer 432 on the silicon substrate 410 surrounding the gate trench 420. The polysilicon gate 440 within the gate trench 420 would not be oxidized in the present step because of the protection of the dielectric structure 474 and the etching protection layer 472′. The silicon oxide layer 432 can be regarded as a patterned layer because of the gate trench 420. The thickness of the silicon oxide layer 432 decides the depth of the source region. As a preferred embodiment, the lower edge of the silicon oxide layer 432 is substantially aligned to the upper surface of the polysilicon gate 440.

Next, as shown in FIG. 4E, the silicon oxide layer 432 is removed by selectively etching but the dielectric structure 474 as well as the etching protection layer 472′ are remained. The selectively etching step depicted in the first embodiment can be applied in the present embodiment. That is, a photo-resist layer 490 may be formed on the upper surface of the dielectric structure 474 first, and then the silicon oxide layer 432 is removed through the open of the photo-resist layer 490 by etching. The dielectric structure 474 would be remained on the polysilicon gate 440 because of the protection of the photo-resist layer 490 and the etching protection layer 472′.

Next, as shown in FIG. 4F, the photo-resist layer 490 is removed, and then the etching protection layer 472′ on the sidewall of the dielectric structure 474 is removed to leave the portion of the etching protection layer, which is labeled by 472″, at the bottom of the dielectric structure 474. Thereafter, as shown in FIG. 4G, the body 450 and the source region 460 are formed in the silicon substrate 410 by ion implantation. Then, as shown in FIG. 4H, a spacer 476 is formed on the side surface of the dielectric structure 474 to define the contact window 480. Afterward, the silicon substrate 410 is etched by using the spacer 476 as the etching mask to form the contact window therein for exposing the source region 460.

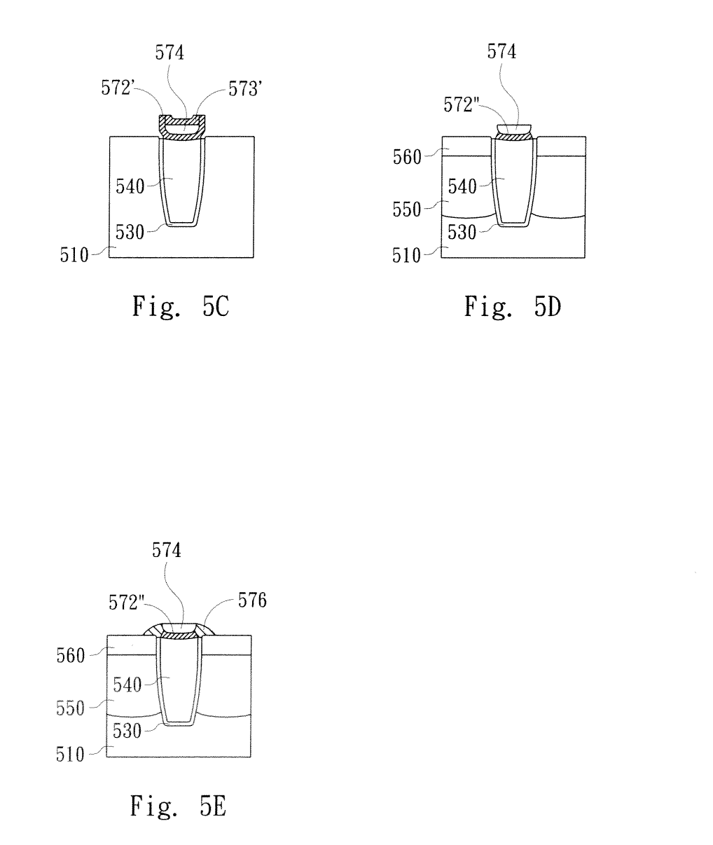

FIGS. 5A to 5E are schematic cross-section views showing a fabrication method of a high cell-density trenched power semiconductor structure in accordance with a fourth embodiment of the present invention. The fabrication step of FIG. 5A is next to the fabrication of FIG. 2B. As shown, a first etching protection layer 572 is conformally formed on the silicon oxide patterned layer 522 and the polysilicon gate 540. The first etching protection layer 572 shows a concave thereon corresponding to the open of the silicon oxide patterned layer 522. Then, a first dielectric structure 574 is formed in the concave. The first dielectric structure 574 may be fabricated by using the method as depicted in the first embodiment of the present invention but an adequate space in the concave should be kept above the first dielectric structure 574 for the following fabrication steps.

Thereafter, a second etching protection layer 573 is conformally formed on the first etching protection layer 572 and the first dielectric structure 574. The second etching protection layer 573 also shows a concave thereon corresponding to the location of the first dielectric structure 574. Then, a second dielectric structure 575 is formed in the concave on the second etching protection layer 573. The second dielectric structure 575 may be fabricated by using the fabrication method as depicted in the first embodiment of the present invention. In addition, the first dielectric structure 574 and the second dielectric structure 575 may be formed of silicon oxide.

Next, as shown in FIG. 5B, the portions of the first etching protection layer 572 and the second etching protection layer above the silicon oxide patterned layer 522 are removed to leave the portions of the first etching protection layer and the second etching protection layer, which are labeled by 572′ and 573′ respectively, within the open of the silicon oxide patterned layer 522. The present fabrication step may be performed by using the selective etching process to selectively remove the exposed portions of first etching protection layer 572 and the second etching protection layer 573. The second dielectric structure 575 as well as the portions of the first etching protection layer 572′ and the second protection layer 573′ shielded by the second dielectric structure 575 are remained.

Next, as shown in FIG. 5C, the silicon oxide patterned layer 522 is removed by selective etching with the first etching protection layer 572′ and the second etching protection layer 573′ as the etching mask so as to prevent the first dielectric structure 574 from being removed. However, the second dielectric structure 575 would be removed in the present etching step.

The above mentioned first etching protection layer 572 and the second etching protection layer 573 can be formed of the same material, such as silicon nitride. However, this should not be a limitation of the present invention. According to the present embodiment, the first etching protection layer 572 and the second etching protection layer 573 are selectively etched by using the second dielectric structure 575 as the etching mask, and then the remained portions of the first protection layer 572′ and the second etching protection layer 573′ are functioned as the etching mask for selectively etching the silicon oxide patterned layer 522. The only limitation for the composition of the first etching protection layer 572 and the second etching protection layer 573 is to meet the requirement of the above mentioned selective etching steps.

Next, as shown in FIG. 5D, the exposed first etching protection layer 572′ and the second etching protection layer 573′ are removed to leave the first dielectric structure 574. A portion of the first etching protection layer, which is labeled by 572″, is still remained at the bottom of the first dielectric structure 574. Then, the body 550 and the source region 560 are formed in the silicon substrate 510 by ion implantation. Thereafter, as shown in FIG. 5E, a spacer 576 is formed on the side surface of the dielectric structure 574. The silicon substrate 510 is then etched through the spacer 576 to form the source contact window 580 for exposing the source region 560.

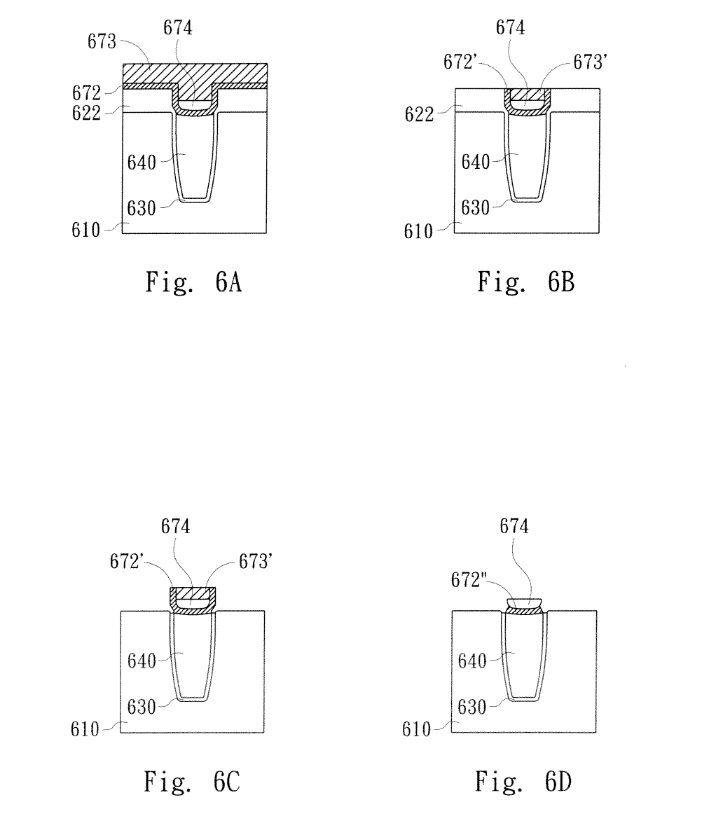

FIGS. 6A to 6D are schematic cross-section views showing a fabrication method of a high cell density trenched power semiconductor structure in accordance with a fifth embodiment of the present invention. In contrast with the fourth embodiment of the present invention, which features a second etching protection layer 573 and a second dielectric structure 575 on the first dielectric structure 574, the present embodiment has a thicker second etching protection layer 673 deposited on the first etching protection layer 672 and the dielectric structure 674. The second etching protection layer 673 fills the open of the silicon oxide patterned layer 622.

Next, as shown in FIG. 6B, the portions of the first etching protection layer 672 and the second etching protection layer 673 above the silicon oxide patterned layer 622 are removed to expose the upper surface of the silicon oxide patterned layer 622. The typical etch back process can be applied in the present etching step. After the etching step, only the portions of the first etching protection layer and the second etching protection layer within the open of the silicon oxide patterned layer 622, which are labeled by 672′ and 673′ respectively, are remained.

Next, as shown in FIG. 6C, the remained first etching protection layer 672′ and the remained second etching protection layer 673′ are utilized as the mask to remove the silicon oxide patterned layer 622 and keep the dielectric structure 674 on the polysilicon gate 640. Afterward, as shown in FIG. 6D, the exposed first etching protection layer 672′ and the second etching protection layer 673′ are removed to leave the dielectric structure 674 together with the portion of the first etching protection, which is labeled by 672″, at the bottom of the dielectric structure 674. The following steps, which may be identical to the above mentioned embodiments, are not repeated here.

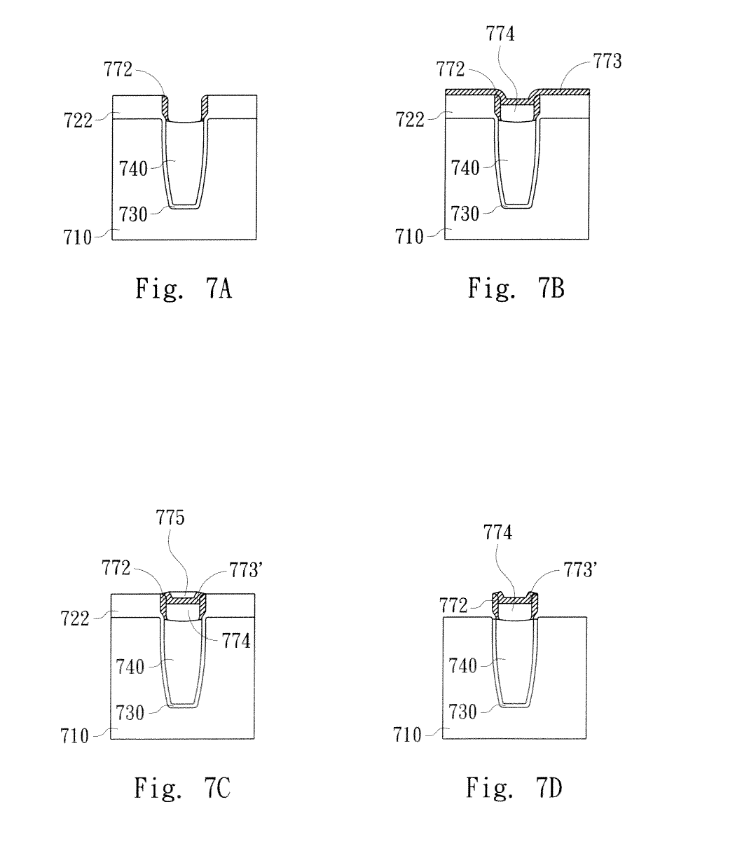

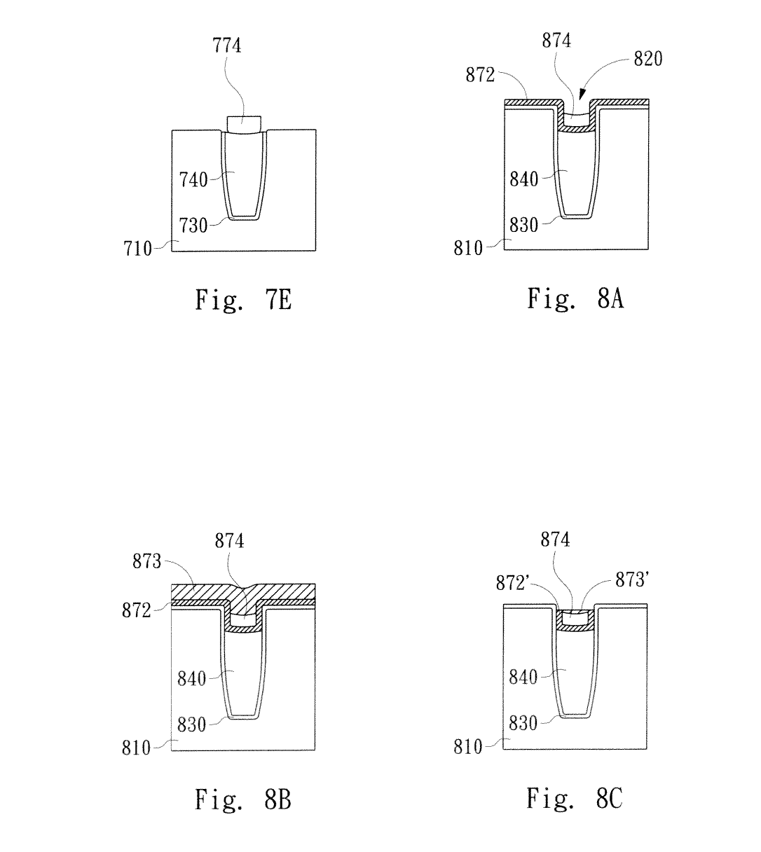

FIGS. 7A to 7E are schematic cross-section views showing a fabrication method of a high cell density trenched power semiconductor structure in accordance with a sixth embodiment of the present invention. Similar to the second embodiment of the present invention, an anisotropic etching step is performed right after the formation of the first etching protection layer on the silicon oxide patterned layer 722 and the polysilicon gate 740 to leave the portion of the first etching protection layer, which is labeled by 772, on the sidewall of the open of the silicon oxide patterned layer 722.

Next, as shown in FIG. 7B, similar to the fourth embodiment of the present invention, a first dielectric structure 772 is formed in the open of the silicon oxide patterned layer 722. Thereafter, a second etching protection layer 773 is conformally formed on the first etching protection layer 772, the first dielectric structure 774, and the silicon oxide patterned layer 722. The second etching protection layer 773 shows a concave thereon aligned to the first dielectric structure 774. Then, as shown in FIG. 7C, a second dielectric structure 775 is formed in the concave on the second etching protection layer 773. Afterward, the portion of the second etching protection layer 773 on the silicon oxide patterned layer 722 is removed by using the second dielectric structure 775 as the mask, and the portion of the second etching protection layer within the open of the silicon oxide patterned layer 722, which is labeled by 773′, is remained.

Next, as shown in FIG. 7D, by using the first etching protection layer 772 and the remained second etching protection layer 773′ as the etching mask, the silicon oxide patterned layer 722 is removed and the first dielectric structure 774 is remained on the polysilicon gate 740. The exposed second dielectric structure 775 is also removed in the present step. Thereafter, as shown in FIG. 7E, the exposed first etching protection layer 722 and the second etching protection layer 773′ are removed to leave the first dielectric structure 774. The following steps, which are similar to the above mentioned embodiments, are not repeated here.

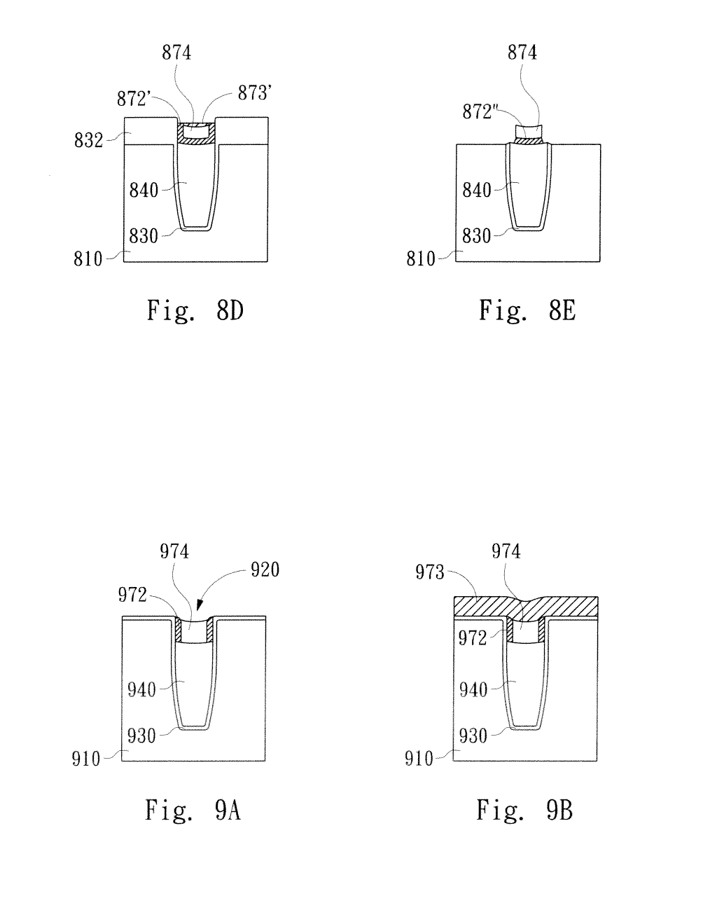

FIGS. 8A to 8E are schematic cross-section views showing a fabrication method of a high cell density trenched power semiconductor structure in accordance with a seventh embodiment of the present invention. The fabrication step of FIG. 8A is next to the fabrication step of FIG. 4A. As shown in FIG. 8A, a first etching protection layer 872 is conformally formed on the silicon substrate 810 and the polysilicon gate 840. The first etching protection layer 872 shows a concave thereon right above the polysilicon gate 840. Thereafter, a dielectric structure 874 is formed in the concave. The dielectric structure 874 is located above the polysilicon gate 840 and a maximum width of the dielectric structure 874 is smaller than a width of the open of the gate trench 820. In addition, the upper surface of the dielectric structure 874 is located below the open of the gate trench 820.

Next, as shown in FIG. 8B, a second etching protection layer 873 with a greater thickness is deposited on the first dielectric protection layer 872 and the dielectric structure 874. The second etching protection layer 873 fills the concave on the first etching protection layer 872. Thereafter, as shown in FIG. 8C, the portions of the first etching protection layer 872 and the second etching protection layer 873 on the silicon substrate 810 are removed by etching, but the portions within the gate trench 820, which are labeled by 872′ and 873′ respectively, are remained. The remained first etching protection layer 872′ is located on the bottom and the sidewall of the dielectric structure 874, and the remained second etching protection layer 873′ covers the upper surface of the dielectric structure 874.

Next, as shown in FIG. 8D, an oxidizing step is carried out to selectively oxidize the silicon substrate 810 by using the first etching protection layer 872′ and the second etching protection layer 873′ as the mask. A silicon oxide layer 832 is thus formed on the silicon substrate 810. As a preferred embodiment, the lower surface of the silicon oxide layer 832 is substantially aligned to the upper surface of the polysilicon gate 840. Thereafter, as shown in FIG. 8E, the exposed silicon oxide layer 832 is removed by selective etching so as to show the protruding dielectric structure 874 with the first etching protection layer 872′ and the second etching protection layer 873′ formed thereon. Then, another selective etching step is performed to remove the second etching protection layer 873′ and the first etching protection layer 872′ on the sidewall of the dielectric structure 874 so as to expose the dielectric structure 874. After the etching step, only the portion of the first etching protection layer at the bottom of the dielectric structure 874, which is labeled by 872″, is left. The following steps, which are similar to the above mentioned embodiments, are not repeated here.

FIGS. 9A to 9B are schematic cross-section views showing a fabrication method of a high cell density trenched power semiconductor structure in accordance with an eighth embodiment of the present invention. The fabrication step of FIG. 9A is next to the fabrication step of FIG. 4A. Different from the seventh embodiment of the present invention, the present embodiment features a first etching protection layer 972 which only covers the sidewall of the gate trench 920. Thus, the dielectric structure 974, which is then formed in the gate trench 920, is connected to the polysilicon gate 940. The sidewall of the dielectric structure 974 is shielded by the first etching protection layer 972 in contrast. In addition, the upper surface of the dielectric structure 974 is located below the open of the gate trench 920.

Thereafter, as shown in FIG. 9B, a second etching protection layer 973 with a greater thickness is formed on the silicon substrate 910 and the dielectric structure 974. The second etching protection layer 973 fills the gate trench 920. Thereafter, the portion of the second etching protection layer 973 on the upper surface of the silicon substrate 910 is removed by etching and the portion of the second etching protection layer within the gate trench 920, which is labeled by 973′, is remained to show a structure similar to FIG. 8C. The following steps of the present embodiment are similar to that of the seventh embodiment and thus are not repeated here. In conclusion, the major difference between the present embodiment and the seventh embodiment is that the first etching protection layer 972 of the present embodiment merely covers the sidewall of the dielectric structure 974, and thus there would be no first etching protection layer 972 remained between the dielectric structure 974 and the polysilicon gate 940.

As to the typical trenched power semiconductor structure, the distance between the gate trench 120 and the contact window 180 is restricted by the critical dimensions of the gate trench 120 and the contact window 280 as well as alignment errors. In contrast, the trenched power semiconductor structure of the present invention applies the self alignment approach to form the dielectric structure 274 on the polysilicon gate 240 and uses the spacer 276 on the side surface of the dielectric structure 274 to define the location of the contact window 280. Thus, the difficulty of alignment control and the limitation of critical dimensions can be overcome, and the object of high cell density can be achieved.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A fabrication method of a high cell density trenched power semiconductor structure comprising the steps of:
forming at least a gate trench in a substrate with a silicon oxide patterned layer formed thereon, said silicon oxide patterned layer having at least an open aligned to the gate trench;
forming a polysilicon gate in the gate trench;
forming a dielectric structure in the open, the dielectric structure having a sidewall thereof being lined with an etching protection layer;
removing the silicon oxide patterned layer by selective etching; and
forming a spacer on a side surface of the dielectric structure to define at least a contact window.

2. The fabrication method of a high cell density trenched power semiconductor structure of claim 1, wherein said silicon oxide patterned layer is utilized for defining the gate trench.

3. The fabrication method of a high cell density trenched power semiconductor structure of claim 1, wherein said silicon oxide patterned layer is formed by oxidizing the substrate after the dielectric structure is formed to shield the polysilicon gate.

4. The fabrication method of a high cell density trenched power semiconductor structure of claim 1, after the step of removing the silicon oxide patterned layer, further comprising the step of removing the etching protection layer by selective etching.

5. The fabrication method of a high cell density trenched power semiconductor structure of claim 1, wherein the step of removing the silicon oxide patterned layer by selective etching comprises:
forming a photo-resist layer, which has a line width thereof being greater than a width of the open of the silicon oxide patterned layer, to shield the dielectric structure; and
etching the silicon oxide patterned layer through the photo-resist layer.

6. The fabrication method of a high cell density trenched power semiconductor structure of claim 1, further comprising:
forming a second etching protection layer to shield the dielectric structure in the open;
removing a portion of the second etching protection layer to expose the silicon oxide patterned layer; and
wherein the silicon oxide patterned layer is etched with the dielectric structure being shielded by the remained second etching protection layer.

7. The fabrication method of a high cell density trenched power semiconductor structure of claim 6, wherein the second etching protection layer substantially fills the open of the silicon oxide patterned layer, and the step of removing the second etching protection layer to expose the silicon oxide patterned layer is carried out by using etching back technology.

8. The fabrication method of a high cell density trenched power semiconductor structure of claim 6, wherein the step of removing the second etching protection layer to expose the silicon oxide patterned layer comprises:
forming a second dielectric structure on the second etching protection layer, the second dielectric structure being aligned to the open; and
removing an exposed portion of the second etching protection layer;
wherein, the silicon oxide patterned layer is etched with the dielectric structure being shielded by the remained second etching protection layer beneath the second dielectric structure.

9. The fabrication method of a high cell density trenched power semiconductor structure of claim 8, wherein the second etching protection layer shows a concave thereon for allocating the second dielectric structure, which is formed by using etching back technology.

10. The fabrication method of a high cell density power semiconductor structure of claim 1, wherein the dielectric structure is formed of silicon oxide and the etching protection layer is formed of silicon nitride or polysilicon.

11. The fabrication method of a high cell density trenched power semiconductor structure of claim 3, wherein the step of oxidizing the substrate to form the silicon oxide patterned layer comprises:
forming a second etching protection layer on the silicon substrate to shield the dielectric structure in the gate trench;
removing the second etching protection layer to expose the silicon substrate; and
oxidizing the silicon substrate to form the silicon oxide patterned layer with the dielectric structure being shielded by the remained second etching protection layer.

12. The fabrication method of a high cell density trenched power semiconductor structure of claim 11, wherein the second etching protection layer formed on the silicon substrate fills the gate trench and the step of removing the protection layer to expose the upper surface of the silicon substrate is carried out by using etching back technology.

13. The fabrication method of a high cell density trenched power semiconductor structure of claim 11, wherein the step of removing the second etching protection layer to expose the silicon substrate comprises:
forming a second dielectric structure on the second etching protection layer, the second dielectric structure being aligned to the gate trench; and
removing an exposed portion of the second etching protection layer.

14. The fabrication method of a high cell density trenched power semiconductor structure of claim 13, wherein the second etching protection layer is conformally formed on the patterned layer and shows a concave thereon corresponding the open, and the concave is for allocating the second dielectric structure, which is formed on the second etching protection layer by using etching back technology.

15. The high cell density trenched power semiconductor structure comprises:
a silicon substrate;
a gate trench located in the silicon substrate;
a polysilicon gate located in the gate trench;
a body located in the silicon substrate and surrounding the gate trench;
a source region located in the body;
a dielectric structure located above the polysilicon gate and protruded from the gate trench, a maximum width of the dielectric structure being smaller than that of the gate trench; and
a spacer located on a side surface of the dielectric structure for defining at least a contact window to expose the source region.

16. The high cell density trenched power semiconductor structure of claim 15, further comprising an etching protection layer interposed between the dielectric structure and the polysilicon gate.

17. The high cell density trenched power semiconductor structure of claim 15, further comprising an etching protection layer covering the side surface of the dielectric structure.
